(19) United States
(12) Patent Application Publication
(10) Pub. No.: US 2026/0301644 A1
(43) Pub. Date: Oct. 1, 2026

(54) SHIFT REGISTER, A GATE DRIVING CIRCUIT AND A DISPLAY PANEL

(71) Applicant: Beijing Visionox Technology Co., Ltd., Beijing (CN)

(72) Inventors: Jianjun LU, Beijing (CN); Cuili GAI, Beijing (CN); Enqing GUO, Beijing (CN)

(73) Assignee: Beijing Visionox Technology Co., Ltd., Beijing (CN)

(21) Appl. No.: 19/698,759

(22) Filed: Jun. 4, 2026

(30) Foreign Application Priority Data
Nov. 20, 2025 (CN) 202511713643.5

(51) Int. Cl. G09G 3/22; G11C 19/28

(52) U.S. Cl. CPC G09G 3/22; G11C 19/28; G09G 2300/0819; G09G 2300/0842; G09G 2300/0861; G09G 2310/0286; G09G 2310/08; G09G 2330/021

(57) ABSTRACT

Disclosed are a shift register, a gate driving circuit, and a display panel. The shift register includes first and second control modules and first and second output modules. The first control module transmits a first or second power supply signal to a first node. The second control module transmits a first or third power supply signal to a second node under control of a potential of the first node, to output an inverted potential at the second node. The second output module transmits to a second output terminal, in response to a potential of the second node, a second output signal at a potential of the first power supply signal, and in response to a potential of a third node, a second output signal at a potential of a second clock signal. One shift register thereby outputs two kinds of scanning signals, is more integrated, and realizes a narrow bezel.

### CROSS REFERENCE TO RELATED APPLICATION

The present application claims priority to Chinese Patent Application No. 202511713643.5, filed on Nov. 20, 2025, which is incorporated herein by reference in its entirety.

### FIELD

The present application relates to the field of display technology, and particularly relates to a shift register, a gate driving circuit and a display panel.

### BACKGROUND

With a development of display technology, a narrow bezel of a display panel has become a major development trend.

In a display panel, a scanning circuit and a light emission control signal generating circuit are usually included, the scanning circuit only provides a scanning signal, the light emission control signal generating circuit only provides a light emission control signal, both the scanning circuit and the light emission control signal generating circuit occupy a bezel area, making it difficult for the display panel to achieve a narrow bezel.

### SUMMARY

The present application provides a shift register, a gate driving circuit and a display panel, to achieve outputting two kinds of scanning signals through one shift register, making the shift register more integrated, and thereby realizing a narrow bezel.

An embodiment of the present application provides a shift register, including: a first control module, a second control module, a first output module and a second output module; the first control module includes a first node, and is configured to transmit a first power supply signal or a second power supply signal to the first node according to a first clock signal, an inverted signal of the first clock signal and an input signal, a potential of the first power supply signal and a potential of the second power supply signal are different; the second control module includes a second node, the second control module is connected to the first node, and is configured to transmit the first power supply signal or a third power supply signal to the second node under control of at least a potential of the first node, to output an inverted potential of the first node at the second node; the first output module includes a first output terminal, the first output module is connected to the first node and the second node respectively, and is configured to transmit a first output signal having the potential of the first power supply signal to the first output terminal in response to the potential of the first node, or transmit the first output signal having the potential of the second power supply signal to the first output terminal in response to a potential of the second node; the second output module includes a second output terminal, the second output module is connected to the second node and a third node respectively, a potential of the third node is an inverted potential of the potential of the second node, the second output module is configured to transmit a second output signal having the potential of the first power supply signal to the second output terminal in response to the potential of the second node, or transmit the second output signal having a potential of a second clock signal to the second output terminal in response to the potential of the third node.

An embodiment of the present application provides a gate driving circuit, including the shift register provided by any embodiment of the present application.

An embodiment of the present application provides a driving method for a shift register, applied to the shift register provided by any embodiment of the present application, the driving method includes: a first control module transmits a first power supply signal or a second power supply signal to a first node according to a first clock signal, an inverted signal of the first clock signal and an input signal; and a potential of the first power supply signal and a potential of the second power supply signal are different; a second control module transmits a first power supply signal or a third power supply signal to a second node under control of at least a potential of the first node, to output an inverted potential of the first node at the second node; a first output module transmits a first output signal having the potential of the first power supply signal to a first output terminal in response to the potential of the first node, or transmits the first output signal having the potential of the second power supply signal to the first output terminal in response to a potential of the second node; a second output module transmits a second output signal having the potential of the first power supply signal to a second output terminal in response to the potential of the second node, or transmits the second output signal having a potential of a second clock signal to the second output terminal in response to a potential of a third node; and the potential of the third node is an inverted potential of the potential of the second node.

An embodiment of the present application provides a display panel, including the gate driving circuit provided by any embodiment of the present application, and further includes a pixel circuit, the pixel circuit includes a data writing transistor, a compensation transistor, an initialization transistor and a light emission control transistor; a first output terminal of the gate driving circuit is connected to a gate of the light emission control transistor, and is configured to provide a light emission control signal to the light emission control transistor; a second output terminal of the gate driving circuit is connected to a gate of the data writing transistor, a gate of the compensation transistor or a gate of the initialization transistor, and is configured to provide a scanning signal to the data writing transistor, the compensation transistor or the initialization transistor.

The shift register provided by the embodiment of the present application, by configuring the shift register to include a first control module, a second control module, a first output module and a second output module, enables the shift register to simultaneously output two kinds of scanning signals through a first output terminal and a second output terminal, when the shift register is applied to a display panel, the shift register may simultaneously provide a scanning signal and a light emission control signal for a pixel circuit in the display panel, compared with a shift register in a scanning circuit and a shift register in a light emission control signal generating circuit that are independently arranged in an existing display panel, the shift register provided by the embodiment can integrate two functions of providing the scanning signal and the light emission control signal, which is beneficial to reducing a number of components and signal lines, and further beneficial to realizing a narrow bezel of the display panel.

Content described in this section is not intended to identify a key or an important feature of the embodiments of the present application, nor is the content used to limit a scope of the present application. Other features of the present application will become easily understandable through the following description.

### BRIEF DESCRIPTION OF THE DRAWINGS

To describe some embodiments of the present application more clearly, the following briefly introduces accompanying drawings required for describing the embodiments. In one embodiment, the accompanying drawings in the following description are only some embodiments of the present application.

FIG. 1 is a structural schematic diagram of a shift register provided by an embodiment of the present application;

FIG. 2 is a driving timing diagram of the shift register provided by an embodiment of the present application;

FIG. 3 is a structural schematic diagram of another shift register provided by an embodiment of the present application;

FIG. 4 is a structural schematic diagram of another shift register provided by an embodiment of the present application;

FIG. 5 is a structural schematic diagram of another shift register provided by an embodiment of the present application;

FIG. 6 is a structural schematic diagram of another shift register provided by an embodiment of the present application;

FIG. 7 is a structural schematic diagram of another shift register provided by an embodiment of the present application;

FIG. 8 is a structural schematic diagram of another shift register provided by an embodiment of the present application;

FIG. 9 is a structural schematic diagram of another shift register provided by an embodiment of the present application;

FIG. 10 is a structural schematic diagram of another shift register provided by an embodiment of the present application;

FIG. 11 is a driving timing diagram of another shift register provided by an embodiment of the present application;

FIG. 12 is a structural schematic diagram of a gate driving circuit provided by an embodiment of the present application;

FIG. 13 is a simulation waveform diagram of a driving timing provided by an embodiment of the present application;

FIG. 14 is a flowchart of a driving method for a shift register provided by an embodiment of the present application;

FIG. 15 is a flowchart of another driving method for a shift register provided by an embodiment of the present application;

FIG. 16 is a flowchart of another driving method for a shift register provided by an embodiment of the present application;

FIG. 17 is a structural schematic diagram of a display panel provided by an embodiment of the present application;

FIG. 18 is a structural schematic diagram of a pixel circuit provided by an embodiment of the present application.

### DETAILED DESCRIPTION

To enable a person to better understand solutions of the present application, embodiments of the present application will be clearly and completely described below in conjunction with accompanying drawings in the embodiments of the present application. In one embodiment, the described embodiments are only some embodiments of the present application, rather than all embodiments.

Terms “first”, “second”, etc. in a specification and claims of the present application and the above accompanying drawings are used to distinguish similar objects, and are not necessarily used to describe a specific sequence or an order. Data used in one embodiment, are interchangeable under appropriate circumstances, and the embodiments of the present application described herein can be implemented in sequences other than those illustrated or described herein. In addition, terms “comprise” and “have” and any variations thereof are intended to cover a non-exclusive inclusion.

As described in the background, an existing display panel usually includes a scanning circuit and a light emission control signal generating circuit, the scanning circuit only provides a scanning signal, the light emission control signal generating circuit only provides a light emission control signal, both the scanning circuit and the light emission control signal generating circuit occupy a bezel area, making it difficult for the display panel to achieve a narrow bezel. Through research, an inventor found that a reason for the above problem is that a shift register of the scanning circuit and a shift register of the light emission control signal generating circuit are independently arranged, that is, devices and signal lines included in the two circuits are not shared, causing a bezel area of the display panel to include more devices and signal lines, making it difficult for the display panel to achieve a narrow bezel.

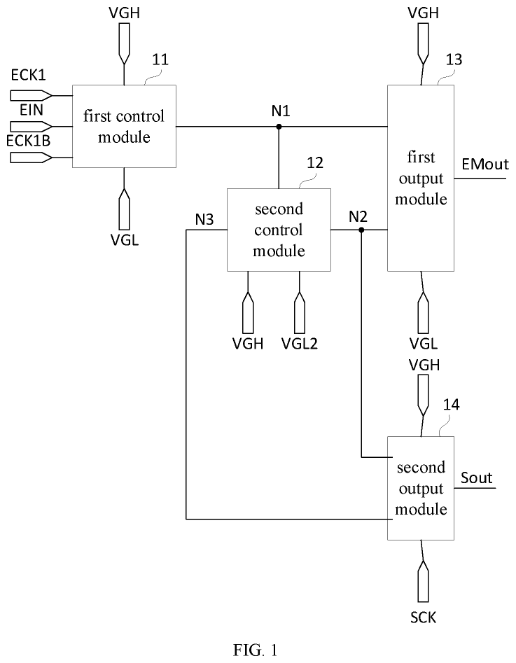

Based on the above reason, an embodiment of the present application provides a shift register. FIG. 1 is a structural schematic diagram of a shift register provided by an embodiment of the present application. Referring to FIG. 1, the shift register includes a first control module 11, a second control module 12, a first output module 13 and a second output module 14.

The first control module 11 includes a first node N1, and is configured to transmit a first power supply signal VGH or a second power supply signal VGL to the first node N1 according to a first clock signal ECK1, an inverted signal ECK1B of the first clock signal and an input signal EIN, and a potential of the first power supply signal VGH and a potential of the second power supply signal VGL are different.

The second control module 12 includes a second node N2, the second control module 12 is connected to the first node N1, and is configured to transmit the first power supply signal VGH or a third power supply signal VGL2 to the second node N2 under control of at least the potential of the first node N1, to output an inverted potential of the first node N1 at the second node N2.

The first output module 13 includes a first output terminal, the first output module 13 is connected to the first node N1 and the second node N2 respectively, and is configured to transmit a first output signal EMout having the potential of the first power supply signal VGH to the first output terminal in response to the potential of the first node N1, or transmit the first output signal EMout having the potential of the second power supply signal VGL to the first output terminal in response to the potential of the second node N2.

The second output module 14 includes a second output terminal, the second output module 14 is connected to the second node N2 and a third node N3 respectively, a potential of the third node N3 is an inverted potential of the potential of the second node N2, the second output module 14 is configured to transmit a second output signal Sout having the potential of the first power supply signal VGH to the second output terminal in response to the potential of the second node N2, or transmit the second output signal Sout having a potential of a second clock signal SCK to the second output terminal in response to the potential of the third node N3.

In one embodiment, the input signal EIN may be a pulse signal including a high potential signal and a low potential signal. A potential of the high potential signal is higher than that of the low potential signal. The input signal EIN may be configured according to an actual condition, in an embodiment, as an input from an external circuit or an output signal of a previous stage shift register. In an actual implementation, the shift register may be used for a display panel, the display panel includes a gate driving circuit composed of multiple cascaded shift registers, and an input signal input terminal of a first stage shift register is electrically connected to a start signal line for receiving the input signal EIN, an input signal input terminal of an (n+1)-th stage shift register is electrically connected to an output terminal of a j-th stage shift register; a scanning signal output by the j-th stage shift register serves as the input signal EIN of a next stage shift register. In one embodiment, j is an integer greater than 0. The shift register may output an effective potential of the input signal EIN after a shift delay.

The first power supply signal VGH and the second power supply signal VGL have opposite potentials, in an embodiment, when the first power supply signal VGH is a high potential signal, the second power supply signal VGL is a low potential signal, or when the first power supply signal VGH is a low potential signal, the second power supply signal VGL is a high potential signal. In the present embodiment and the following embodiments, a case where the first power supply signal VGH is a high potential signal and the second power supply signal VGL is a low potential signal is taken as an example for an illustrative description. In an embodiment, a voltage of the third power supply signal VGL2 is lower than a voltage of the second power supply signal VGL.

Within one frame, a duration of an effective potential of the first output signal EMout is greater than a duration of an effective potential of the second output signal Sout. In an embodiment In an embodiment, the first output signal EMout is a light emission control signal, and the second output signal Sout is a scanning signal. In one embodiment, the effective potential is a potential that controls a corresponding transistor to turn on, an ineffective potential is a potential that controls a corresponding transistor to turn off. In an embodiment, the effective potential of the first output signal EMout is a potential signal that turns on a transistor connected to the first output terminal, the effective potential of the second output signal Sout is a potential signal that turns on a transistor connected to the second output terminal. In one embodiment, the effective potential of the first output signal EMout is a high potential, an ineffective potential of the first output signal EMout is a low potential; the effective potential of the second output signal Sout is a high potential, an ineffective potential of the second output signal Sout is a low potential; or, the effective potential of the first output signal EMout is a low potential, the ineffective potential of the first output signal EMout is a high potential; the effective potential of the second output signal Sout is a low potential, an ineffective potential of the second output signal Sout is a high potential. The embodiments of the present application all take a case where the effective potential of the first output signal EMout is a low potential, the ineffective potential of the first output signal EMout is a high potential; the effective potential of the second output signal Sout is a low potential, and the ineffective potential of the second output signal Sout is a high potential as an example for description. In an embodiment, in the present embodiment and the following embodiments, the high potential is greater than a zero potential, and the low potential is less than a zero potential.

A potential corresponding to the second power supply signal VGL is an effective potential of the first output signal EMout, a first potential signal in the second clock signal SCK is an effective potential of the second output signal Sout. The second clock signal includes the first potential signal and a second potential signal, one of the first potential signal and the second potential signal is a high potential signal, and another of the first potential signal and the second potential signal is a low potential signal. In an embodiment, the first potential signal is a low potential signal.

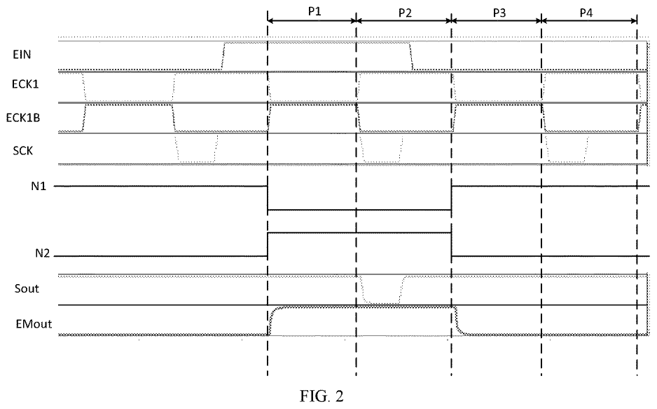

FIG. 2 is a driving timing diagram of a shift register provided by an embodiment of the present application, which may be used to drive the shift register shown in FIG. 1. Referring to FIGS. 1 and 2, the input signal EIN, the first clock signal ECK1, the inverted signal ECK1B of the first clock signal and the second clock signal SCK may include a low potential signal and a high potential signal. In an embodiment, the high potential signal is the same as the first power supply signal VGH, and the low potential signal is the same as the second power supply signal VGL.

Referring to FIGS. 1 and 2, a driving timing of the shift register includes four stages, which are a first stage P1, a second stage P2, a third stage P3 and a fourth stage P4.

In the first stage P1, the input signal EIN, the inverted signal ECK1B of the first clock signal and the second clock signal SCK are all at a high potential, and the first clock signal ECK1 is at a low potential. The first control module 11 transmits the second power supply signal VGL to the first node N1 according to the first clock signal ECK1, the inverted signal ECKB1 of the first clock signal and the input signal EIN, that is, the first node N1 is at a low potential, the second control module 12 transmits the first power supply signal VGH to the second node N2 under control of at least the potential of the first node N1, the second node N2 is at a high potential, since the potential of the third node N3 is an inverted potential of the potential of the second node N2, the potential of the third node N3 is at a low potential. The first output module 13 transmits the first output signal EMout having the potential of the first power supply signal to the first output terminal in response to the potential of the first node N1. The second output module 14 transmits the second output signal Sout having the potential of the second clock signal SCK to the second output terminal in response to the potential of the third node N3. That is, in the first stage P1, the first output signal EMout output by the first output module 13 is a high potential signal, and the second output signal Sout output by the second output module 14 is a high potential signal.

In the second stage P2, the input signal EIN and the first clock signal ECK1 are at a high potential, the inverted signal ECK1B of the first clock signal jumps to a low potential, the second clock signal first jumps to a low potential, and then jumps from a low potential to a high potential. The first node N1 maintains a low potential, the second control module 12 transmits the first power supply signal VGH to the second node N2 under control of at least the potential of the first node N1, the second node N2 is at a high potential, since the potential of the third node N3 is an inverted potential of the potential of the second node N2, the potential of the third node N3 is at a low potential. The first output module 13 transmits the first output signal EMout having the potential of the first power supply signal to the first output terminal in response to the potential of the first node N1. The second output module 14 transmits the second output signal Sout having the potential of the second clock signal SCK to the second output terminal in response to the potential of the third node N3. That is, in the second stage P2, the first output signal EMout output by the first output module 13 is a high potential signal, and the second output signal Sout output by the second output module 14 has the potential of the second clock signal SCK.

In the third stage P3, the input signal EIN and the first clock signal ECK1 jump to a low potential, the inverted signal ECKB1 of the first clock signal jumps to a high potential, and the second clock signal SCK is at a high potential. The first control module 11 transmits the first power supply signal VGH to the first node N1 according to the first clock signal ECK1, the inverted signal ECKB1 of the first clock signal and the input signal EIN, that is, the first node N1 is at a high potential. The second control module 12 transmits the third power supply signal VGL2 to the second node N2 under control of at least the potential of the first node N1, the second node N2 is at a low potential, since the potential of the third node N3 is an inverted potential of the potential of the second node N2, the potential of the third node N3 is at a high potential. The first output module 13 transmits the first output signal EMout having the potential of the second power supply signal VGL to the first output terminal in response to the potential of the second node N2. The second output module 14 transmits the second output signal Sout having the potential of the first power supply signal VGH to the second output terminal in response to the potential of the second node N2. That is, in the third stage P3, the first output signal EMout output by the first output module 13 is a low potential signal, and the second output signal Sout output by the second output module 14 is a high potential signal.

In the fourth stage P4, the input signal EIN and the inverted signal ECK1B of the first clock signal are both at a low potential, and the first clock signal ECK1 jumps to a high potential. The first node N1, the second node N2 and the third node N3 maintain the potentials of the third stage P3. That is, in the fourth stage P4, the first output signal EMout output by the first output module 13 is a low potential signal, and the second output signal Sout output by the second output module 14 is the second clock signal SCK. Subsequently, the third stage P3 and the fourth stage P4 are continuously repeated, and will not be described in detail.

The shift register provided by the embodiment of the present application, by configuring the shift register to include a first control module, a second control module, a first output module and a second output module, enables the shift register to simultaneously output two kinds of scanning signals through a first output terminal and a second output terminal, when the shift register is applied to a display panel, the shift register may simultaneously provide a scanning signal and a light emission control signal for a pixel circuit in the display panel, compared with a shift register in a scanning circuit and a shift register in a light emission control signal generating circuit that are independently arranged in an existing display panel, the shift register provided by the embodiment can integrate two functions of providing the scanning signal and the light emission control signal, which is beneficial to reducing a number of components and signal lines, and further beneficial to realizing a narrow bezel of the display panel.

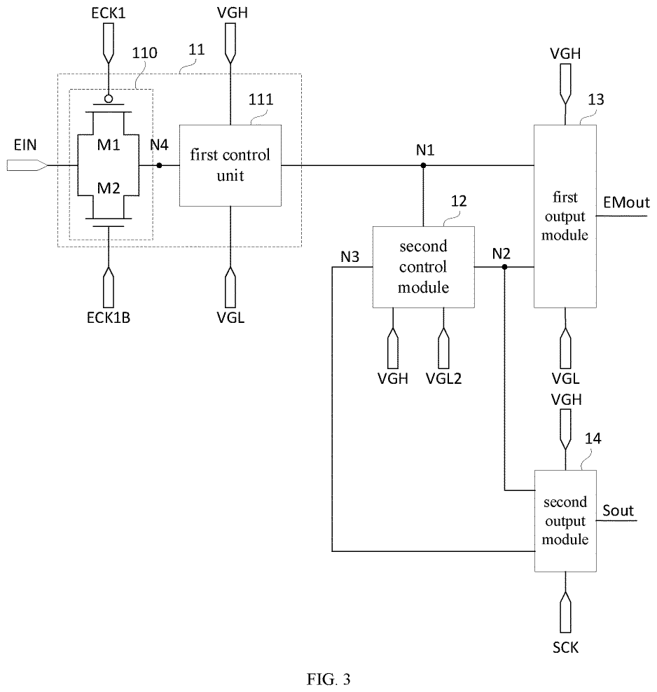

FIG. 3 is a structural schematic diagram of another shift register provided by an embodiment of the present application. Referring to FIG. 3, in an embodiment, the first control module 11 includes an input unit 110 and a first control unit 111, and the input unit 110 and the first control unit 111 are connected at a fourth node N4.

The input unit 110 is configured to receive the input signal EIN, the first clock signal ECK1 and the inverted signal ECK1B of the first clock signal, and transmit the input signal EIN to the fourth node N4 according to the first clock signal ECK1 and the inverted signal ECK1B of the first clock signal.

The first control unit 111 is configured to receive the first power supply signal VGH and the second power supply signal VGL respectively, and the first control unit 111 is configured to transmit the first power supply signal VGH or the second power supply signal VGL to the first node N1 according to a potential of the fourth node N4.

In one embodiment, the input unit 110 may be composed of a transistor or another controllable switching device; the input unit 110 may control a connection state between an input terminal and an output terminal of the input unit 110. When the input unit 110 is turned on, the input terminal and the output terminal are connected, and the input signal EIN may be transmitted to the fourth node N4; when the input unit 110 is turned off, the input terminal and the output terminal are disconnected, and the input signal EIN cannot be transmitted to the fourth node N4. By adjusting a turn-on and turn-off time of the input unit 110, an adjustment of a correspondence between the input signal EIN and the potential of the fourth node N4 may be achieved. In an embodiment, by controlling a switching moment of a turn-on and turn-off state of the input unit 110 to be later than a potential transition moment of the input signal, a potential transition (or a pulse) of the input signal may be transmitted to the fourth node N4 with a delay.

In some embodiments, the first clock signal ECK1 and the second clock signal SCK have a same period, and an effective potential signal of the first clock signal ECK1 and an effective potential signal of the second clock signal SCK at least partially overlap; the effective potential signal of the first clock signal ECK1 is a signal that turns on the input unit 110, and the effective potential signal of the second clock signal SCK is a signal that turns on a transistor connected to the second output terminal.

In an embodiment, a duration of the effective potential signal of the second clock signal SCK is less than a duration of the effective potential signal of the first clock signal ECK1.

In an embodiment, the input unit 110 includes a first transistor M1 and a second transistor M2, a gate of the first transistor M1 is configured to receive the first clock signal ECK1, a first terminal of the first transistor M1 is configured to receive the input signal EIN, and a second terminal of the first transistor M1 is connected to the fourth node N4.

A first gate of the second transistor M2 is configured to receive the inverted signal ECK1B of the first clock signal, a first terminal of the second transistor M2 is configured to receive the input signal EIN, and a second terminal of the second transistor M2 is connected to the fourth node N4; a channel type of the second transistor M2 and a channel type of the first transistor M1 are opposite.

In one embodiment, the first transistor M1 and the second transistor M2 are connected in parallel to form a transmission gate. The first transistor M1 is an N-channel type transistor, and the second transistor M2 is a P-channel type transistor.

In the present embodiment, by configuring the input unit 110 as a transmission gate structure, a reliability of the shift register may be effectively improved. In one embodiment, a P-type transistor has a threshold voltage loss when transmitting a low potential, enabling a high potential to pass through without loss while the low potential passes through with loss; conversely, an N-type transistor has a threshold voltage loss when transmitting a high potential, and can only pass a low potential without loss. The transmission gate structure of the input unit 110 enables both a low potential and a high potential to pass through without loss, effectively ensuring a potential transmission capability of the input unit 110, expanding a range of potentials that the input unit 110 can transmit, thereby ensuring that when the input unit 110 is turned on, the potential of the fourth node N4 is consistent with a potential of the input signal EIN, and avoiding an output abnormality caused by a threshold voltage loss.

When the fourth node N4 is at a low potential, the first control unit 111 transmits the first power supply signal VGH to the first node N1, making the first node N1 at a high potential. When the fourth node N4 is at a high potential, the first control unit 111 transmits the second power supply signal VGL to the first node N1, thereby achieving an inversion of the potential of the first node N1 and the potential of the fourth node N4.

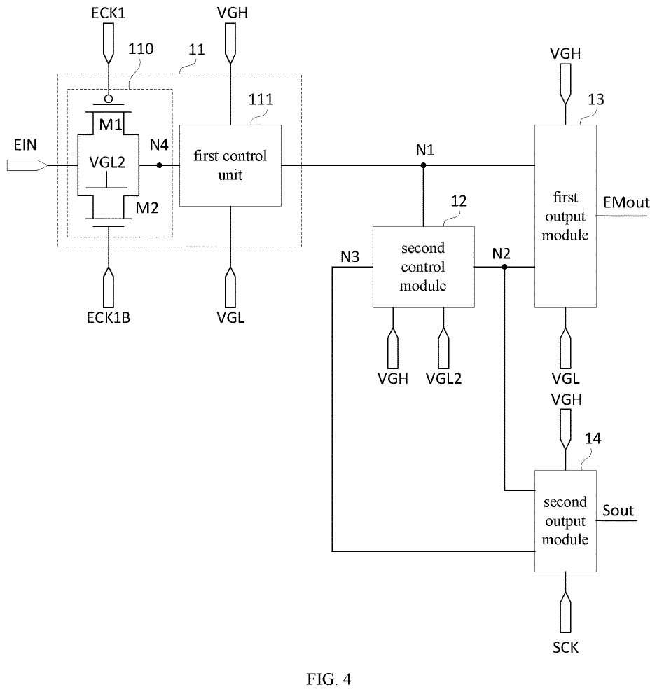

FIG. 4 is a structural schematic diagram of another shift register provided by an embodiment of the present application. Referring to FIG. 4, in an embodiment, the second transistor M2 further includes a second gate, and the second gate is configured to receive the third power supply signal VGL2. In one embodiment, the inverted signal ECK1B of the first clock signal includes a high potential signal and a low potential signal, and a voltage of the third power supply signal VGL2 is lower than a voltage of the low potential signal in the inverted signal ECK1B of the first clock signal.

In one embodiment, the first gate is a top gate of the second transistor M2, the second gate is a bottom gate of the second transistor M2; the second gate of the second transistor M2 is configured to receive the third power supply signal VGL2, to suppress a threshold voltage shift and a fluctuation of the N-type transistor, and to suppress an off-state leakage current of the N-type transistor by regulating a threshold voltage of the N-type transistor; in addition, by regulating a threshold voltage of the third transistor M3, it is ensured that the threshold voltage of the third transistor M3 is greater than 0, improving a yield. The second transistor M2 is a metal oxide transistor. In an embodiment, the N-type transistor may be an IGZO (Indium Gallium Zinc Oxide) transistor, during an operation, a threshold voltage of the IGZO transistor may shift negative, and correspondingly a potential of the third power supply signal VGL2 may be set lower than the voltage of the low potential signal in the inverted signal ECK1B of the first clock signal.

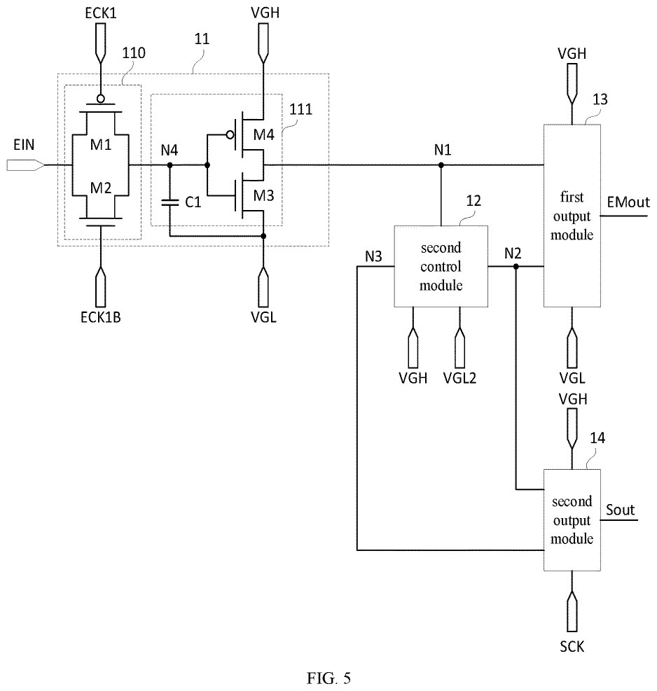

FIG. 5 is a structural schematic diagram of another shift register provided by an embodiment of the present application. Referring to FIG. 5, in an embodiment, the first control unit 111 includes a first inverter unit and a storage unit.

A control terminal of the first inverter unit is connected to the fourth node N4, a first terminal of the first inverter unit is configured to receive the first power supply signal VGH, a second terminal of the first inverter unit is configured to receive the second power supply signal VGL, and the first inverter unit is configured to invert the potential of the fourth node N4 and output the inverted potential to the first node N1.

A first terminal of the storage unit is connected to the fourth node N4, a second terminal of the storage unit is connected to the second terminal of the first inverter unit, and is configured to store the potential of the fourth node N4.

In an embodiment, continuing to refer to FIG. 5, the first inverter unit includes a third transistor M3 and a fourth transistor M4.

A first gate of the third transistor M3 serves as the control terminal of the first inverter unit, a first terminal of the third transistor M3 serves as the second terminal of the first inverter unit, and a second terminal of the third transistor M3 is connected to the first node N1.

A gate of the fourth transistor M4 is connected to the first gate of the third transistor M3, a first terminal of the fourth transistor M4 serves as the first terminal of the first inverter unit, and a second terminal of the fourth transistor M4 is connected to the first node N1.

In one embodiment, when the input unit 110 transmits the input signal EIN to the fourth node N4, pulling a potential of the fourth node N4 high (for example, to a VGH potential), the fourth transistor M4 (for example, a P-type transistor) will be turned off due to a gate of the fourth transistor M4 being at a high potential, while the third transistor M3 (for example, an N-type transistor) will be turned on due to a gate of the third transistor M3 being at a high potential. At this time, the third transistor M3 transmits the second power supply signal VGL (a low potential) to the first node N1, thereby making the potential of the first node N1 low. Conversely, when the potential of the fourth node N4 is low, the fourth transistor M4 is turned on while the third transistor M3 is turned off, the first power supply signal VGH (a high potential) is transmitted to the first node N1 through the fourth transistor M4, making a potential of the first node N1 high.

In an embodiment, continuing to refer to FIG. 5, the storage unit includes a first capacitor C1, a first terminal of the first capacitor C1 serves as the first terminal of the storage unit, and a second terminal of the first capacitor C1 serves as the second terminal of the storage unit.

In one embodiment, the first capacitor C1 plays a key role in a charge storage and a potential maintenance. The first capacitor C1 can store a charge of the fourth node N4, utilizing a characteristic that a voltage across a capacitor cannot change suddenly, effectively latching the potential of the fourth node N4, preventing an unexpected drift of the potential of the fourth node N4 due to a transistor leakage current or a coupling noise, thereby enhancing an anti-interference capability and an operational reliability of an entire shift register circuit.

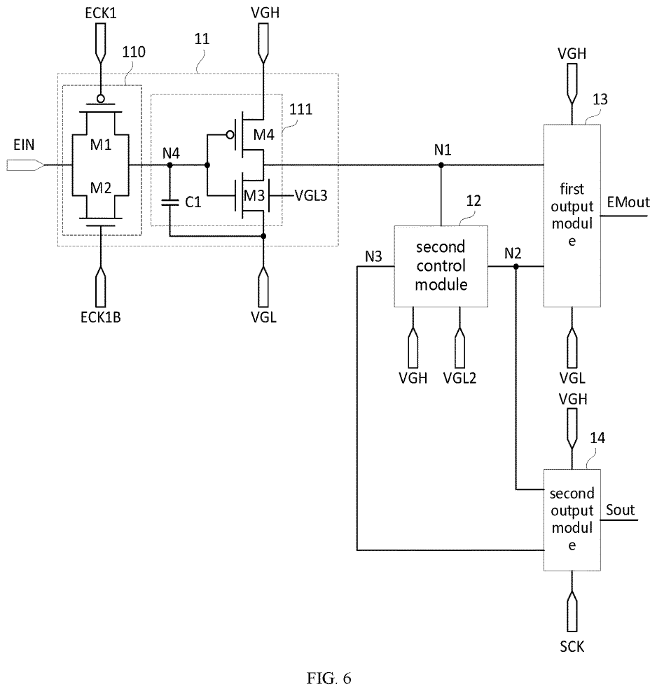

FIG. 6 is a structural schematic diagram of another shift register provided by an embodiment of the present application. Referring to FIG. 6, in an embodiment, the third transistor M3 includes a second gate, the second gate of the third transistor M3 is configured to receive a fourth power supply signal VGL3; the input signal EIN includes a high potential signal and a low potential signal, and a voltage of the fourth power supply signal VGL3 is lower than a voltage of the low potential signal in the input signal EIN. In an embodiment, the third transistor M3 is a metal oxide transistor. Such a configuration can suppress a threshold voltage shift and a fluctuation of the third transistor M3, by regulating a threshold voltage of the third transistor M3, thereby ensuring that the threshold voltage of the third transistor M3 is greater than 0, and improving a yield.

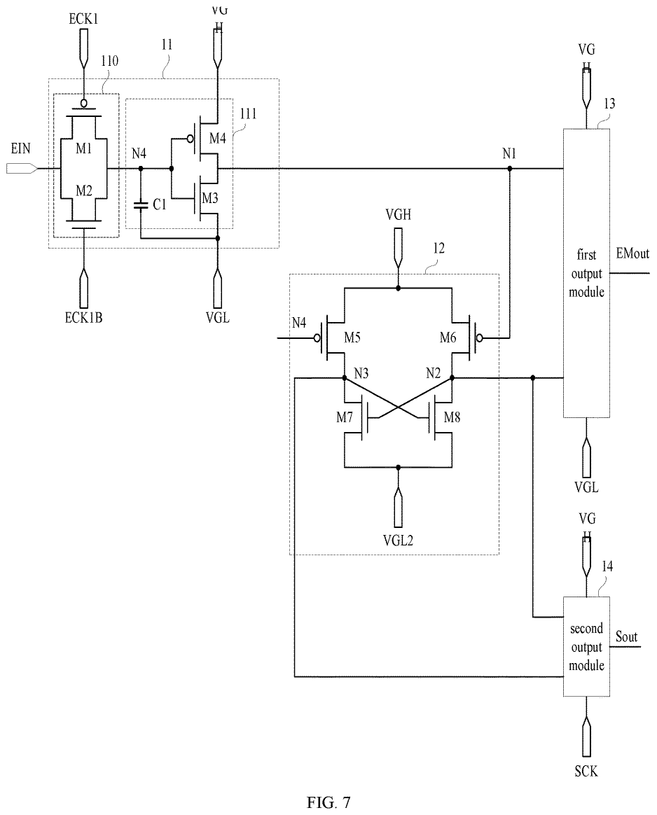

FIG. 7 is a structural schematic diagram of another shift register provided by an embodiment of the present application. Referring to FIG. 7, in an embodiment, the second control module 12 is further connected to the second node N2, the third node N3 and the fourth node N4 respectively, and is configured to transmit the first power supply signal VGH to the second node N2 in response to the potential of the first node N1, and transmit the third power supply signal VGL2 to the third node N3 according to the first power supply signal VGH at the second node N2; and configured to transmit the first power supply signal VGH to the third node N3 in response to the potential of the fourth node N4, and transmit the third power supply signal VGL2 to the second node N2 according to the first power supply signal VGH at the third node N3.

In an embodiment, when the potential of the second node N2 jumps from a low potential to a high potential, the potential of the third node N3 jumps from a high potential to a low potential; when the potential of the second node N2 jumps from a high potential to a low potential, the potential of the third node N3 jumps from a low potential to a high potential. In an embodiment, the potentials of the second node N2 and the third node N3 maintain opposite levels.

In an embodiment, continuing to refer to FIG. 7, the second control module 12 includes a fifth transistor M5, a sixth transistor M6, a seventh transistor M7 and an eighth transistor M8.

A gate of the fifth transistor M5 is connected to the fourth node N4, a first terminal of the fifth transistor M5 is configured to receive the first power supply signal VGH, and a second terminal of the fifth transistor M5 is connected to the third node N3.

A gate of the sixth transistor M6 is connected to the first node N1, a first terminal of the sixth transistor M6 is configured to receive the first power supply signal VGH, and a second terminal of the sixth transistor M6 is connected to the second node N2.

A first gate of the seventh transistor M7 is connected to the second node N2, a first terminal of the seventh transistor M7 is configured to receive the third power supply signal VGL2, and a second terminal of the seventh transistor M7 is connected to the third node N3.

A first gate of the eighth transistor M8 is connected to the third node N3, a first terminal of the eighth transistor M8 is configured to receive the third power supply signal VGL2, and a second terminal of the eighth transistor M8 is connected to the second node N2.

In one embodiment, a channel type of the fifth transistor M5 is opposite to a channel type of the seventh transistor M7, a channel type of the sixth transistor M6 is opposite to a channel type of the eighth transistor M8, and the channel type of the fifth transistor M5 is the same as the channel type of the sixth transistor M6.

Under this connection mode, when the seventh transistor M7 is turned off, a gate of the seventh transistor M7 may be transmitted with the third power supply signal VGL2 by the eighth transistor M8, a source of the seventh transistor M7 is also the third power supply signal VGL2, potentials of the gate and the source of the seventh transistor M7 are equal, therefore a leakage current is small when the seventh transistor M7 is turned off, reducing a power consumption of the gate driving circuit.

In an embodiment, the fifth transistor M5 is a P-type transistor, and/or, the sixth transistor M6 is a P-type transistor, and/or, the seventh transistor M7 is an N-type transistor, and/or, the eighth transistor M8 is an N-type transistor.

A case where the first power supply signal VGH is a high potential signal and the second power supply signal VGL is a low potential signal is taken as an example. When the fourth node N4 is at the second power supply signal VGL and the first node N1 is at the first power supply signal VGH, the fifth transistor M5 is turned on, the sixth transistor M6 is turned off, the first power supply signal VGH is transmitted to a gate of the eighth transistor M8 through the fifth transistor M5, causing the eighth transistor M8 to turn on, transmitting the third power supply signal VGL2 to the second node N2, and the seventh transistor M7 is turned off according to the third power supply signal VGL2. When the fourth node N4 is at the first power supply signal VGH and the first node N1 is at the second power supply signal VGL, the fifth transistor M5 is turned off, the sixth transistor M6 is turned on, the first power supply signal VGH is transmitted to a gate of the seventh transistor M7 and the second node N2 through the sixth transistor M6, the seventh transistor M7 is turned on according to the first power supply signal VGH at the gate, the third power supply signal VGL2 is transmitted to the gate of the eighth transistor M8 through the seventh transistor M7, and the eighth transistor M8 is turned off. Thus, the potential of the second node N2 is positively correlated with the potential of the fourth node N4, and when the potential of the fourth node N4 is the second power supply signal VGL, the potential of the second node N2 is the third power supply signal VGL2.

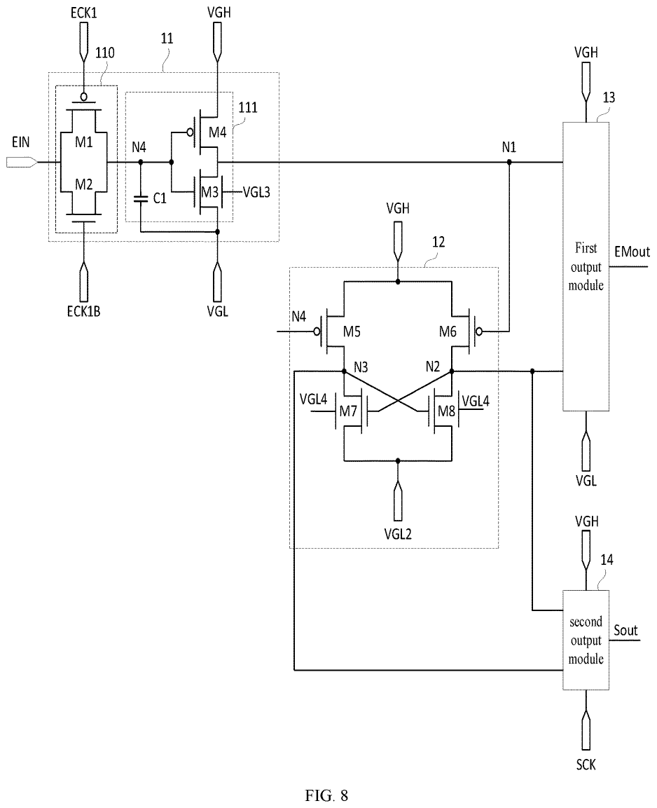

FIG. 8 is a structural schematic diagram of another shift register provided by an embodiment of the present application. Referring to FIG. 8, in an embodiment, the seventh transistor M7 and the eighth transistor M8 both include a second gate, the second gate of the seventh transistor M7 and the second gate of the eighth transistor M8 are both configured to receive a fifth power supply signal VGL4; a voltage of the fifth power supply signal VGL4 is lower than a voltage of the third power supply signal VGL2. Such a configuration can suppress a threshold voltage shift and a fluctuation of the seventh transistor M7 and the eighth transistor M8, by regulating threshold voltages of the seventh transistor M7 and the eighth transistor M8, thereby ensuring that the threshold voltages of the seventh transistor M7 and the eighth transistor M8 are greater than 0, and improving a yield.

In an embodiment, the seventh transistor M7 and the eighth transistor M8 are both metal oxide transistors.

In an embodiment, the second gate of the seventh transistor M7 and the second gate of the eighth transistor M8 both receive a fourth power supply signal VGL3. The fourth power supply signal VGL3 and the fifth power supply signal VGL4 have a same voltage magnitude.

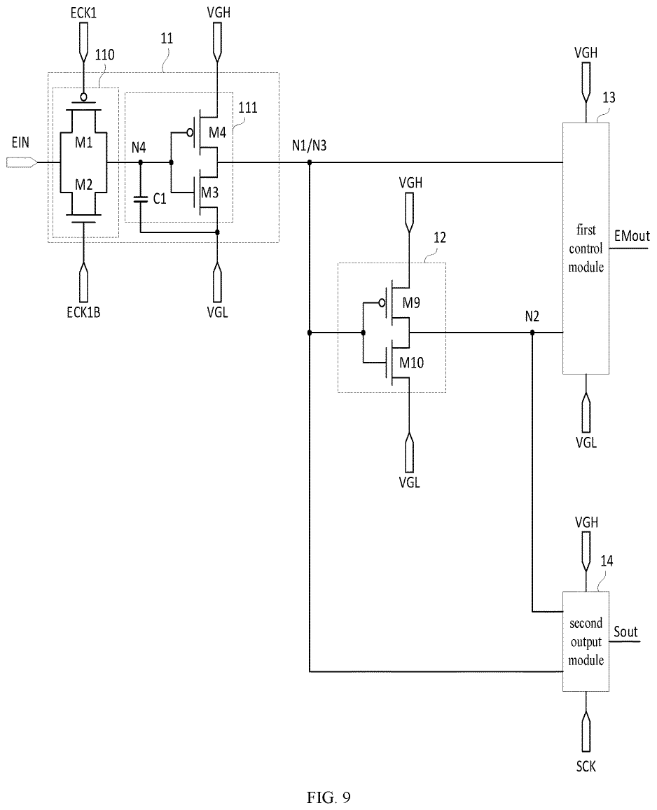

FIG. 9 is a structural schematic diagram of another shift register provided by an embodiment of the present application. Referring to FIG. 9, in an embodiment, the first node N1 is multiplexed as the third node N3, and the second control module 12 includes a second inverter unit.

A control terminal of the second inverter unit is connected to the first node N1, a first terminal of the second inverter unit is configured to receive the first power supply signal VGH, a second terminal of the second inverter unit is configured to receive the second power supply signal VGL, and the second inverter unit is configured to invert the potential of the first node N1 and output the inverted potential to the second node N2.

The second inverter unit includes a ninth transistor M9 and a tenth transistor M10, a gate of the ninth transistor serves as the control terminal of the second inverter unit, a first terminal of the ninth transistor M9 serves as the first terminal of the second inverter unit, and a second terminal of the ninth transistor M9 is connected to the second node N2.

A gate of the tenth transistor M10 is connected to the gate of the ninth transistor M9, a first terminal of the tenth transistor M10 serves as the second terminal of the second inverter unit, and a second terminal of the tenth transistor M10 is connected to the second node N2.

In one embodiment, channel types of the ninth transistor M9 and the tenth transistor M10 are opposite, in an embodiment, the ninth transistor M9 is a P-type transistor while the tenth transistor M10 is an N-type transistor, forming a standard CMOS inverter structure.

When the first control module 11 controls the potential of the first node N1 to a high potential (for example, VGH), the tenth transistor M10 is turned on while the ninth transistor M9 is turned off. At this time, the second power supply signal VGL is transmitted to the second node N2 through the turned-on tenth transistor M10, causing the second node N2 to output a low potential. Conversely, when the potential of the first node N1 is at a low potential (for example, VGL), the ninth transistor M9 is turned on while the tenth transistor M10 is turned off. At this time, the first power supply signal VGH (a high potential) is transmitted to the second node N2 through the turned-on ninth transistor M9, causing the second node N2 to output a high potential. Thus it can be seen that the potential of the second node N2 is always opposite to the potential of the first node N1 (i.e., the multiplexed third node N3), achieving a function of an inverted output.

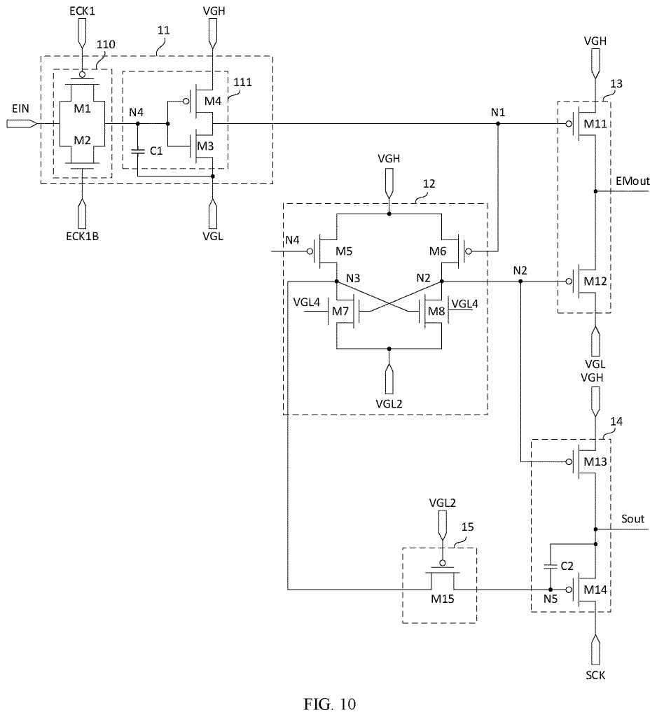

FIG. 10 is a structural schematic diagram of another shift register provided by an embodiment of the present application. Referring to FIG. 10, in an embodiment, the first output module 13 includes: a first output unit and a second output unit.

The first output unit is connected to the first node N1, and is configured to transmit the first power supply signal VGH to the first output terminal according to the potential of the first node N1. The second output unit is connected to the second node N2, and is configured to transmit the second power supply signal VGL to the first output terminal according to the potential of the second node N2.

In an embodiment, the first output unit includes: an eleventh transistor M11, a gate of the eleventh transistor M11 is connected to the first node N1, a first terminal of the eleventh transistor M11 is configured to receive the first power supply signal VGH, and a second terminal of the eleventh transistor M11 is connected to the first output terminal.

The second output unit includes: a twelfth transistor M12, a gate of the twelfth transistor M12 is connected to the second node N2, a first terminal of the twelfth transistor M12 is connected to the second terminal of the eleventh transistor M11 and is connected to the first output terminal, and a second terminal of the twelfth transistor M12 is configured to receive the second power supply signal VGL. In an embodiment, both the eleventh transistor M11 and the twelfth transistor M12 are P-type transistors.

In one embodiment, when the first node N1 is at a low potential, a gate of the eleventh transistor M11 is turned on, thereby transmitting the first power supply signal VGH to the first output terminal. At a same time, the second node N2 is at a high potential, the twelfth transistor M12 is turned off, thereby cutting off a path from the second power supply signal VGL to the first output terminal. At this time, the first output terminal stably outputs the first output signal EMout of a high potential.

When the first node N1 is at a high potential, the eleventh transistor M11 is turned off, cutting off a path of the first power supply signal VGH. The second node N2 becomes a low potential, the twelfth transistor M12 is turned on, transmitting the second power supply signal VGL to the first output terminal. At this time, the first output terminal O stably outputs the first output signal EMout of a low potential.

In an embodiment, the second output module includes a third output unit and a fourth output unit; the third output unit is connected to the second node N2, and is configured to transmit the first power supply signal VGH to the second output terminal according to the potential of the second node N2; the fourth output unit is connected to the third node N3, and is configured to transmit the second clock signal SCK to the second output terminal according to the potential of the third node N3.

In an embodiment, the third output unit includes: a thirteenth transistor M13, a gate of the thirteenth transistor M13 is connected to the second node N2, a first terminal of the thirteenth transistor M13 is configured to receive the first power supply signal VGH, and a second terminal of the thirteenth transistor M13 is connected to the second output terminal.

The fourth output unit includes: a fourteenth transistor M14 and a second capacitor C2, a gate of the fourteenth transistor M14 is connected to the third node N3 and a first terminal of the second capacitor C2 at a fifth node N5, a first terminal of the fourteenth transistor M14 is connected to a second terminal of the second capacitor C2 and is connected to the second output terminal, and a second terminal of the fourteenth transistor M14 is configured to receive the second clock signal SCK. In an embodiment, both the thirteenth transistor M13 and the fourteenth transistor M14 are P-type transistors.

In one embodiment, when the second node N2 is at a low potential and the third node N3 is at a high potential, the thirteenth transistor M13 is turned on, and the fourteenth transistor M14 is turned off. The turned-on thirteenth transistor M13 transmits the first power supply signal VGH to the second output terminal, outputting the second output signal Sout of a high potential. At this time, the fourth output unit is turned off, and is isolated from the second clock signal SCK.

When the second node N2 changes to a high potential and the third node N3 changes to a low potential, the thirteenth transistor M13 is turned off, and the fourteenth transistor M14 is turned on. The turned-on fourteenth transistor M14 transmits the second clock signal SCK to the second output terminal. When the second clock signal SCK is at a low potential, the second output terminal outputs an effective low potential scanning signal.

During a stage when an effective low potential needs to be output, the third node N3 is controlled to a low potential, and the fourteenth transistor M14 is turned on. When the second clock signal SCK transitions from a high potential to a low potential, a purpose of the transition is to generate a low potential (an effective potential) pull-down at the second output terminal through the fourteenth transistor M14. Since the second output terminal is connected to a parasitic capacitance of a subsequent circuit (for example, a gate line load), this is a capacitive load. If there were no second capacitor C2, at a moment when the second clock signal SCK pulls down, a potential of a source (a second terminal, connected to SCK) of the fourteenth transistor M14 drops sharply, while if a potential of a gate of the fourteenth transistor M14 (the third node N3) remains unchanged, a gate-source voltage Vgs of the fourteenth transistor M14 may decrease, thereby weakening a conduction capability of the fourteenth transistor M14, causing a pull-down speed to slow down and an output waveform to deteriorate.

According to a principle that a voltage across a capacitor cannot change suddenly, when a transition of the second clock signal SCK causes a potential of a first terminal of the fourteenth transistor M14 (i.e., the second output terminal) to drop sharply, this change is coupled to a gate of the fourteenth transistor M14 (the third node N3) through the second capacitor C2, causing the potential of the third node N3 to be bootstrapped to an even lower potential. This is equivalent to increasing a negative bias voltage applied to the gate of the fourteenth transistor M14 at a critical moment (for a P-channel transistor, i.e., a lower gate-source voltage Vgs), thereby greatly enhancing a conduction strength of the fourteenth transistor M14. This enables the fourteenth transistor M14 to rapidly pull the potential of the second output terminal down to the low potential of the second clock signal SCK with a larger current, ensuring that the second output signal Sout has a steep falling edge and a stable low potential.

The second control module 12 composed of the fifth transistor M5, the sixth transistor M6, the seventh transistor M7 and the eighth transistor M8 is similar to a Static Random-Access Memory (SRAM) structure, second gates of the seventh transistor M7 and the eighth transistor M8 are connected to the third power supply signal VGL2, a voltage of the third power supply signal VGL2 is less than a voltage of the second power supply signal VGL, ensuring an on state of the twelfth transistor M12, which can reduce a width-to-length ratio of the twelfth transistor M12, and is beneficial for a narrow bezel. In addition, the SRAM-like structure ensures a stability of the potentials of the second node N2 and the third node N3, without a need to set a capacitive device, reducing an area of the shift register, and thereby achieving a narrow bezel.

In an embodiment, the shift register further includes a potential isolation module 15, a control terminal of the potential isolation module 15 is configured to receive the third power supply signal VGL2, a first terminal of the potential isolation module 15 is connected to the third node N3, a second terminal of the potential isolation module 15 is connected to a control terminal of the fourth output unit; a voltage of a third power supply signal VGL3 is lower than a voltage of a low potential signal in the second clock signal SCK.

In an embodiment, the potential isolation module 15 includes: a fifteenth transistor M15; a gate of the fifteenth transistor M15 serves as the control terminal of the potential isolation module 15, a first terminal of the fifteenth transistor M15 serves as the first terminal of the potential isolation module 15, and a second terminal of the fifteenth transistor M15 serves as the second terminal of the potential isolation module 15.

Taking a case where the fifteenth transistor M15 is a P-type transistor as an example, a setting of the fifteenth transistor M15 can make it so that when a potential of the control terminal of the fourth output unit is coupled to an extremely low potential, the extremely low potential is isolated by the fifteenth transistor M15 and will not be transmitted to the third node N3, thereby protecting a transistor connected to the fifteenth transistor M15 in the second control module 12 from a damage due to an excessive voltage difference, and improving a reliability of the shift register.

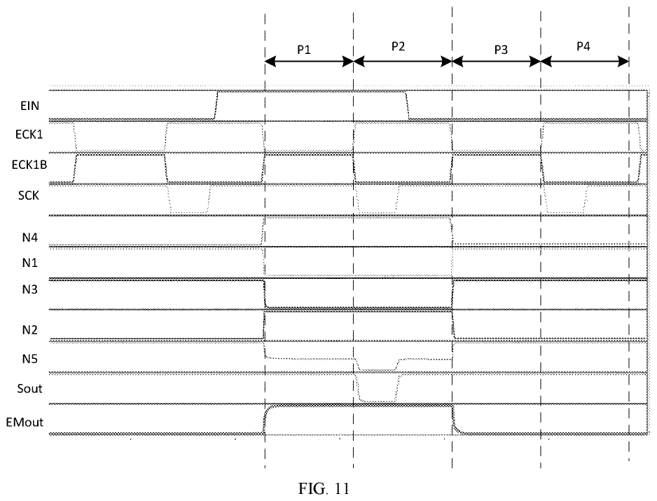

FIG. 11 is a driving timing diagram of another shift register provided by an embodiment of the present application. The diagram may be used to drive the shift register shown in FIG. 10. Referring to FIGS. 10 and 11, the input signal EIN, the first clock signal ECK1, the inverted signal ECK1B of the first clock signal and the second clock signal SCK may include a low potential signal and a high potential signal. In an embodiment, the high potential signal is the same as the first power supply signal VGH, and the low potential signal is the same as the second power supply signal VGL.

Referring to FIGS. 10 and 11, a driving timing of the shift register includes four stages, which are a first stage P1, a second stage P2, a third stage P3 and a fourth stage P4.

In the first stage P1, the input signal EIN, the inverted signal ECK1B of the first clock signal and the second clock signal SCK are all at a high potential, and the first clock signal ECK1 is at a low potential. The first transistor M1 is turned on in response to the first clock signal ECK1, the second transistor M2 is turned on in response to the inverted signal ECKB1 of the first clock signal, transmitting the input signal EIN to the fourth node N4, that is, the fourth node N4 is at a high potential. The third transistor M3 is turned on in response to the high potential of the fourth node N4 to transmit the second power supply signal VGL to the first node N1, that is, the first node N1 is at a low potential. The sixth transistor M6 is turned on in response to the low potential of the first node N1, transmitting the first power supply signal VGH to the second node N2, the second node N2 is at a high potential, the seventh transistor M7 is turned on in response to the high potential of the second node N2, transmitting the third power supply signal VGL2 to the third node N3, therefore the potential of the third node N3 is at a low potential. The eleventh transistor M11 transmits the first output signal EMout having the potential of the first power supply signal to the first output terminal in response to the low potential of the first node N1. The fourteenth transistor M14 transmits the second output signal Sout having the potential of the second clock signal SCK to the second output terminal in response to the low potential of the third node N3. That is, in the first stage P1, the first output signal EMout output by the first output module 13 is a high potential signal, and the second output signal Sout output by the second output module 14 is a high potential signal.

In the second stage P2, the input signal EIN and the first clock signal ECK1 are at a high potential, the inverted signal ECK1B of the first clock signal jumps to a low potential, the second clock signal first jumps to a low potential, and then jumps from a low potential to a high potential. The first transistor M1 and the second transistor M2 are turned off, the fourth node N4 maintains the high potential of the first stage P1, the first node N1 maintains the low potential of the first stage P1, the sixth transistor M6 is turned on in response to the low potential of the first node N1, transmitting the first power supply signal VGH to the second node N2, the second node N2 is at a high potential, the seventh transistor M7 is turned on in response to the high potential of the second node N2, transmitting the third power supply signal VGL2 to the third node N3, therefore the potential of the third node N3 is at a low potential. The eleventh transistor M11 transmits the first output signal EMout having the potential of the first power supply signal to the first output terminal in response to the low potential of the first node N1. The fourteenth transistor M14 transmits the second output signal Sout having the potential of the second clock signal SCK to the second output terminal in response to the low potential of the third node N3. That is, in the second stage P2, the first output signal EMout output by the first output module 13 is a high potential signal, and the second output signal Sout output by the second output module 14 is the second clock signal SCK. Since the second clock signal SCK jumps from a high potential to a low potential, the fifth node N5 is coupled to an extremely low voltage through the second capacitor C2, the fourteenth transistor M14 outputs the second clock signal SCK, a potential of the fifth node N5 jumps downward from the third power supply signal VGL2, therefore the voltage is extremely low, at this time a width-to-length ratio of the fourteenth transistor M14 can be reduced, which is beneficial for a narrow bezel.

In the third stage P3, the input signal EIN and the first clock signal ECK1 jump to a low potential, the inverted signal ECKB1 of the first clock signal jumps to a high potential, and a second clock signal CLK2 is at a high potential. The first transistor M1 is turned on in response to the first clock signal ECK1, the second transistor M2 is turned on in response to the inverted signal ECKB1 of the first clock signal, transmitting the input signal EIN to the fourth node N4, that is, the fourth node N4 is at a low potential. The fourth transistor M4 is turned on in response to the low potential of the fourth node N4 to transmit the first power supply signal VGH to the first node N1, that is, the first node N1 is at a high potential, and the eleventh transistor M11 is turned off. The sixth transistor M6 is turned off, the fifth transistor M5 is turned on in response to the low potential of the fourth node N4, transmitting the first power supply signal VGH to the third node N3, the third node N3 is at a high potential, and the thirteenth transistor M13 is turned off. The eighth transistor M8 is turned on in response to the high potential of the third node N3, transmitting the third power supply signal VGL2 to the second node N2, therefore the potential of the second node N2 is at a low potential. The twelfth transistor M12 transmits the first output signal EMout having the potential of the second power supply signal VGL to the first output terminal in response to the low potential of the second node N2. The thirteenth transistor M13 transmits the second output signal Sout having the potential of the first power supply signal VGH to the second output terminal in response to the low potential of the second node N2. That is, in the third stage P3, the first output signal EMout output by the first output module 13 is a low potential signal, and the second output signal Sout output by the second output module 14 is a high potential signal.

In the fourth stage P4, the input signal EIN and the inverted signal ECK1B of the first clock signal are both at a low potential, and the first clock signal ECK1 jumps to a high potential. The first node N1, the second node N2 and the third node N3 maintain the potentials of the third stage P3. That is, in the fourth stage P4, the first output signal EMout output by the first output module 13 is a low potential signal, and the second output signal Sout output by the second output module 14 is the second clock signal SCK. Subsequently, the third stage P3 and the fourth stage P4 are continuously repeated, and will not be described in detail.

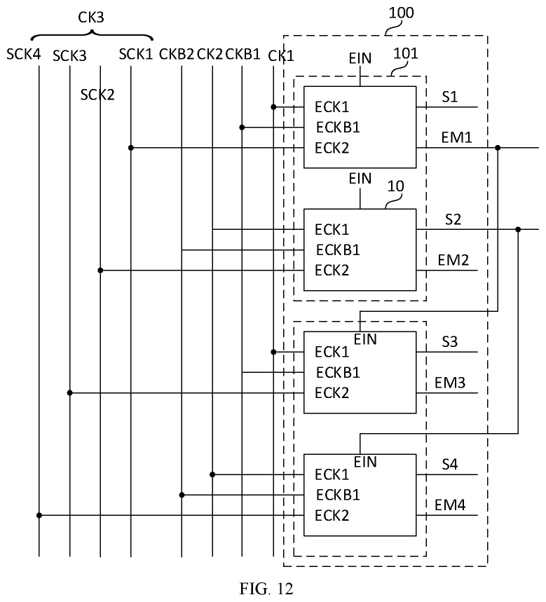

Based on a same inventive concept, an embodiment of the present application provides a gate driving circuit, including the shift register 10 provided by any embodiment of the present application, and having a same functional module and a beneficial effect as the shift register. FIG. 12 is a structural schematic diagram of a gate driving circuit provided by an embodiment of the present application. As shown in FIG. 12, the gate driving circuit 100 includes m number of shift register groups 101, m is an integer greater than or equal to 1, a shift register group 101 includes k number of shift registers 10, the k number of shift registers 10 are connected in a cascade connection through a first output terminal, a first stage shift register in the shift register group 101 is configured to receive the input signal EIN; k is an integer greater than or equal to 2.

The gate driving circuit 100 further includes a first clock signal line CK1, a second clock signal line CK2 and m number of groups of third clock signal lines CK3, each group of the third clock signal lines includes two third clock signal lines; the first clock signal line CK1 is configured to provide the first clock signal ECK1 to an i-th stage shift register 10, the second clock signal line CK2 is configured to provide the first clock signal ECK1 to a j-th stage shift register 10, and i is an odd number greater than or equal to 1 and less than or equal to k, and j is an even number greater than 1 and less than or equal to k.

One of the third clock signal lines in a p-th group of the third clock signal lines CK3 is connected to an odd stage shift register 10 in a p-th shift register group 101, another of the third clock signal lines in the p-th group of the third clock signal lines CK3 is connected to an even stage shift register 10 in the p-th shift register group 101, and p is greater than or equal to 1 and less than or equal to m.

In one embodiment, the first clock signal line CK1, in one embodiment, provides the first clock signal ECK1 to an i-th stage (i.e., an odd stage, i=1,3,5 . . . ) shift register 10 in all shift register groups; while the second clock signal line CK2, in one embodiment, provides the first clock signal ECK1 to a j-th stage (i.e., an even stage, j=2,4,6 . . . ) shift register 10 in all shift register groups. By driving an odd stage shift register and an even stage shift register separately through two lines CK1 and CK2 for the first clock signal ECK1, and also driving the second clock signal SCK separately for the odd stage shift register and the even stage shift register within each group, a total clock load (i.e., a total capacitance of all shift register clock input terminals) is effectively distributed across multiple signal lines. This avoids a problem such as a signal delay, a waveform distortion and an increased power consumption caused by an excessive load on a single signal line, ensuring that the clock signal can still maintain a steep edge and an accurate timing when transmitted to a terminal shift register.

Each group of the third clock signal lines CK3 includes two signal lines for providing the second clock signal SCK. For a p-th group (p=1,2, . . . , m) of the shift register group 101, one of the third clock signal lines in the group is connected to all odd stage shift registers in the group, while another of the third clock signal lines is connected to all even stage shift registers in the group.

FIG. 12 schematically shows a case where m=2 and k=2. That is to say, one of the third clock signal lines SCK1 in a first group of the third clock signal lines CK3 is connected to an odd stage shift register 10 in a first shift register group 101, another of the third clock signal lines SCK2 in the first group of the third clock signal lines CK3 is connected to an even stage shift register 10 in the first shift register group 101.

One of the third clock signal lines SCK3 in a second group of the third clock signal lines CK3 is connected to an odd stage shift register 10 in a second shift register group 101, another of the third clock signal lines SCK4 in the second group of the third clock signal lines CK3 is connected to an even stage shift register 10 in the second shift register group 101.

In an embodiment, continuing to refer to FIG. 12, the gate driving circuit further includes a first inverted clock signal line CKB1 and a second inverted clock signal line CKB2.

The first inverted clock signal line CKB1 is configured to provide an inverted signal ECKB1 of the first clock signal to the i-th stage shift register 10, and the second inverted clock signal line CKB2 is configured to provide the inverted signal ECKB1 of the first clock signal to the j-th stage shift register 10.

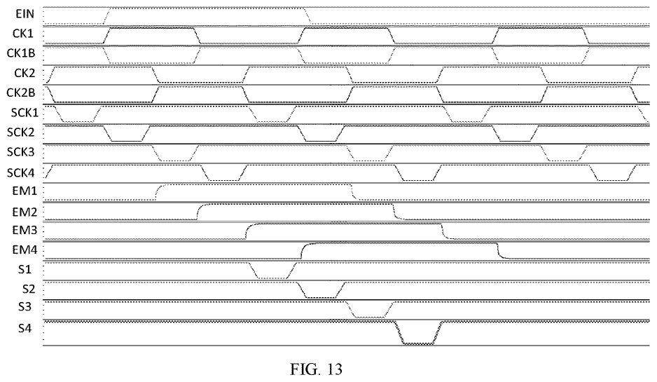

FIG. 13 is a simulation waveform diagram of a driving timing provided by an embodiment of the present application. As shown in FIG. 13, a signal transmitted by the second clock signal line CK2 and a signal transmitted by the first clock signal line CK1 have an equal period, and the signal transmitted by the second clock signal line CK2 has a phase delay relative to the signal transmitted by the first clock signal line CK1.

A signal transmitted by the second inverted clock signal line CKB2 and a signal transmitted by the first inverted clock signal line CKB1 have an equal period, and the signal transmitted by the second inverted clock signal line CKB2 has a phase delay relative to a signal transmitted by the first inverted clock signal line CKB1.

In an embodiment, in each group of the third clock signal lines CK3, a phase of a signal transmitted by a third clock signal line connected to an even stage shift register 10 has a phase delay relative to a phase of a signal transmitted by a third clock signal line CK3 connected to an odd stage shift register 10. That is to say, a signal transmitted by SCK1 has a phase delay relative to a signal transmitted by SCK2. A signal transmitted by SCK3 has a phase delay relative to a signal transmitted by SCK4.

In an embodiment, in two groups of the third clock signal lines corresponding to two adjacent groups of shift registers 10, a signal transmitted by a third clock signal line CK3 connected to an odd stage shift register in a latter group of the third clock signal lines CK3 has a phase delay relative to a signal transmitted by a third clock signal line CK3 connected to an even stage shift register in a former group of the third clock signal lines CK3. That is to say, a signal transmitted by SCK3 has a delay relative to a signal transmitted by SCK2.

EM1 is a first output signal output by a first stage shift register, S1 is a second output signal output by the first stage shift register; EM2 is a first output signal output by a second stage shift register, S2 is a second output signal output by the second stage shift register; EM3 is a first output signal output by a third stage shift register, S3 is a second output signal output by the third stage shift register; EM4 is a first output signal output by a fourth stage shift register, and S4 is a second output signal output by the fourth stage shift register.

In an embodiment, in the m number of shift register groups, an effective potential signal output by a first stage is sequentially delayed.

In an embodiment, a first delay time is equal to a second delay time.

In one embodiment, the first delay time is a phase delay time of a signal transmitted by the second clock signal line CK2 relative to a signal transmitted by the first clock signal line CK1.

The second delay time is a phase delay time of a signal transmitted by a third clock signal line CK3 connected to an odd stage shift register 10 in a latter group of the third clock signal lines CK3 relative to a signal transmitted by a third clock signal line CK3 connected to an even stage shift register in a former group of the third clock signal lines CK3, in two groups of the third clock signal lines corresponding to two adjacent groups of shift registers 10, and/or, the second delay time is a phase delay time of a phase of a signal transmitted by a third clock signal line CK3 connected to an even stage shift register relative to a phase of a signal transmitted by a third clock signal line CK3 connected to an odd stage shift register in each group of the third clock signal lines CK3.

That is to say, a delay time of a signal transmitted by SCK3 relative to a signal transmitted by SCK2 is equal to a phase delay time of a signal transmitted by the second clock signal line CK2 relative to a signal transmitted by the first clock signal line CK1; and/or, a delay time of a signal transmitted by SCK4 relative to a signal transmitted by SCK3 is equal to a phase delay time of a signal transmitted by the second clock signal line CK2 relative to a signal transmitted by the first clock signal line CK1. And/or, a delay time of a signal transmitted by SCK2 relative to a signal transmitted by SCK1 is equal to a phase delay time of a signal transmitted by the second clock signal line CK2 relative to a signal transmitted by the first clock signal line CK1.

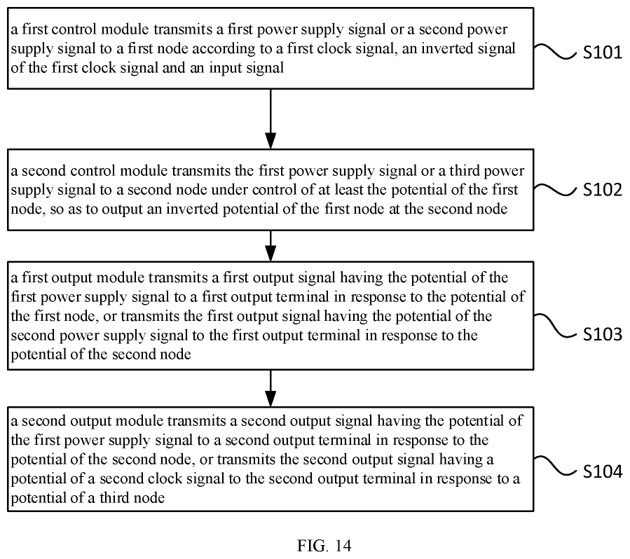

Based on a same inventive concept, an embodiment of the present application further provides a driving method for a shift register, applied to the shift register provided by any embodiment of the present application. FIG. 14 is a flowchart of a driving method for a shift register provided by an embodiment of the present application. As shown in FIG. 14, the driving method includes:
S101, a first control module transmits a first power supply signal or a second power supply signal to a first node according to a first clock signal, an inverted signal of the first clock signal and an input signal.

In one embodiment, a potential of the first power supply signal and a potential of the second power supply signal are different.
S102, a second control module transmits a first power supply signal or a third power supply signal to a second node under control of at least a potential of the first node, to output an inverted potential of the first node at the second node.
S103, a first output module transmits a first output signal having the potential of the first power supply signal to a first output terminal in response to the potential of the first node, or transmits the first output signal having a potential of the second power supply signal to the first output terminal in response to a potential of the second node.
S104, a second output module transmits a second output signal having the potential of the first power supply signal to a second output terminal in response to the potential of the second node, or transmits the second output signal having a potential of a second clock signal to the second output terminal in response to a potential of a third node.

In one embodiment, the potential of the third node is an inverted potential of the potential of the second node.

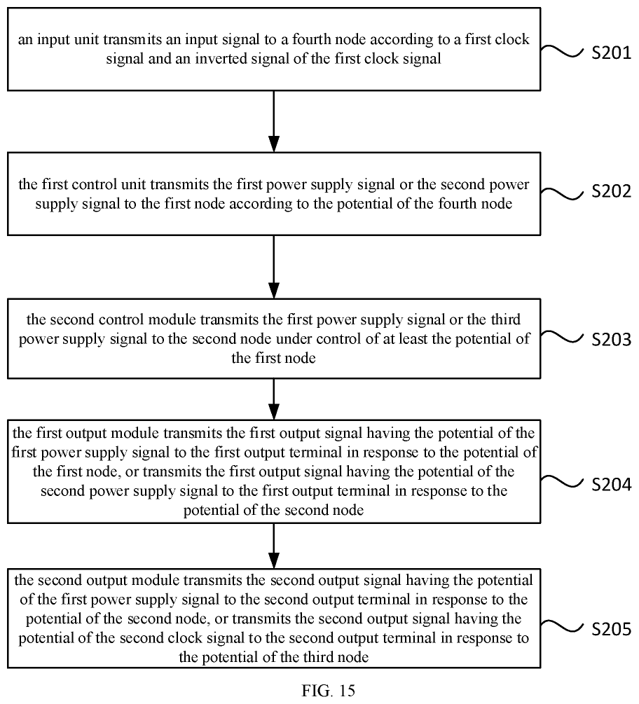

FIG. 15 is a flowchart of another driving method for a shift register provided by an embodiment of the present application. As shown in FIG. 15, the driving method includes:
S201, an input unit transmits an input signal to a fourth node according to a first clock signal and an inverted signal of the first clock signal.

In an embodiment, a first control unit includes a first inverter unit and a storage unit; a step of the first control unit transmitting a first power supply signal or a second power supply signal to a first node according to a potential of the fourth node includes: the first inverter unit inverts the potential of the fourth node and outputs the inverted potential to the first node; the storage unit stores the potential of the fourth node.
S202, the first control unit transmits the first power supply signal or the second power supply signal to the first node according to the potential of the fourth node.
S203, a second control module transmits a first power supply signal or a third power supply signal to a second node under control of at least a potential of the first node, to output an inverted potential of the first node at the second node.
S204, a first output module transmits a first output signal having the potential of the first power supply signal to a first output terminal in response to the potential of the first node, or transmits the first output signal having a potential of the second power supply signal to the first output terminal in response to a potential of the second node.
S205, a second output module transmits a second output signal having the potential of the first power supply signal to a second output terminal in response to the potential of the second node, or transmits the second output signal having a potential of a second clock signal to the second output terminal in response to a potential of the third node.

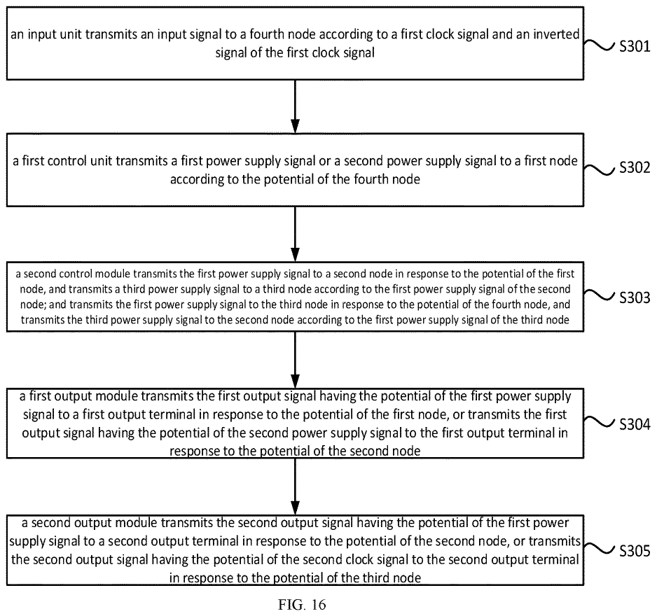

FIG. 16 is a flowchart of another driving method for a shift register provided by an embodiment of the present application. As shown in FIG. 16, the driving method includes:
S301, an input unit transmits an input signal to a fourth node according to a first clock signal and an inverted signal of the first clock signal.
S302, a first control unit transmits a first power supply signal or a second power supply signal to a first node according to a potential of the fourth node.
S303, a second control module transmits a first power supply signal to a second node in response to a potential of a first node, and transmits a third power supply signal to a third node according to the first power supply signal at the second node; and transmits the first power supply signal to the third node in response to the potential of the fourth node, and transmits the third power supply signal to the second node according to the first power supply signal at the third node.

In one embodiment, a voltage of the third power supply signal is lower than a voltage of a second power supply signal.
S304, a first output module transmits a first output signal having the potential of the first power supply signal to a first output terminal in response to the potential of the first node, or transmits the first output signal having a potential of the second power supply signal to the first output terminal in response to a potential of the second node.
S305, a second output module transmits a second output signal having the potential of the first power supply signal to a second output terminal in response to the potential of the second node, or transmits the second output signal having a potential of a second clock signal to the second output terminal in response to a potential of the third node.

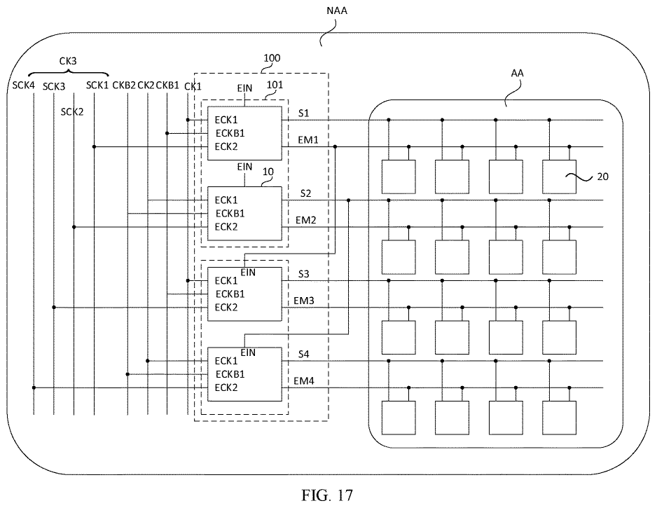

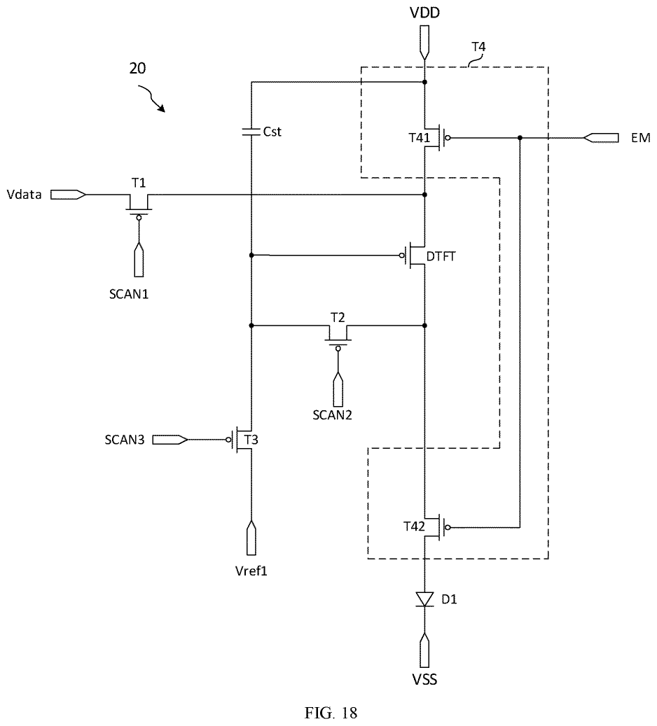

FIG. 17 is a structural schematic diagram of a display panel provided by an embodiment of the present application. FIG. 18 is a structural schematic diagram of a pixel circuit provided by an embodiment of the present application. As shown in FIGS. 17 and 18, a display panel includes the gate driving circuit 100 provided by any embodiment of the present application, and further includes a pixel circuit 20, the pixel circuit 20 includes a data writing transistor T1, a compensation transistor T2, an initialization transistor T3 and a light emission control transistor T4.

A first output terminal of the gate driving circuit 100 is connected to a gate of the light emission control transistor T4, and is configured to provide a light emission control signal EM to the light emission control transistor T4.

A second output terminal of the gate driving circuit 100 is connected to a gate of the data writing transistor T1, a gate of the compensation transistor T2 or a gate of the initialization transistor T3, and is configured to provide a scanning signal to the data writing transistor T1, the compensation transistor T2 or the initialization transistor T3.

In one embodiment, the display panel includes a display area AA and a non-display area NAA, multiple pixel circuits 20 are arranged in an array in the display area AA, and the gate driving circuit 100 is disposed in the non-display area NAA of the display panel.

A first output terminal of each stage shift register is connected to a light emission control transistor T4 in a row of pixel circuits 20 through a corresponding first gate driving signal line, a second output terminal of each stage shift register is connected to a data writing transistor T1, a compensation transistor T2 or an initialization transistor T3 in a row of pixel circuits 20 through a corresponding second gate driving signal line.

Further, in the gate driving circuit 100 of the display panel, multiple cascaded shift registers 10 will output multiple scanning signals that are sequentially delayed in time. These scanning signals are further distributed to different pixel rows, and may serve as a gate control signal for controlling the data writing transistor T1, the compensation transistor T2 or the initialization transistor T3 in a pixel circuit of the row. In an embodiment, the scanning signal may be, in one embodiment, implemented as a first scanning signal SCAN1, a second scanning signal SCAN2 or a third scanning signal SCAN3.

Continuing to refer to FIG. 15, the pixel circuit 20 further includes a driving transistor DTFT. A first terminal of the data writing transistor T1 is connected to a first terminal of the driving transistor DTFT, a second terminal of the data writing transistor T1 is connected to a data line Vdata, and a gate of the data writing transistor T1 is configured to receive the first scanning signal SCAN1.

A gate of the compensation transistor T2 is configured to receive the second scanning signal SCAN2, a first terminal of the compensation transistor T2 is connected to a second terminal of the driving transistor DTFT, and a second terminal of the compensation transistor T2 is connected to a gate of the driving transistor DTFT.

A first terminal of the initialization transistor T3 is connected to the gate of the driving transistor DTFT, a second terminal of the initialization transistor T3 is connected to a first initialization signal line Vref1, and a gate of the initialization transistor T3 is configured to receive a third scanning signal SCAN3. In one embodiment, the data writing transistor T1, the compensation transistor T2 and the initialization transistor T3 are all P-type transistors.

The light emission control transistor T4 includes a first light emission control transistor T41 and a second light emission control transistor T42, a first terminal of the first light emission control transistor T41 is connected to a first power supply line VDD, a second terminal of the first light emission control transistor T41 is connected to the first terminal of the driving transistor DTFT, and a gate of the first light emission control transistor T41 is configured to receive the light emission control signal EM. Both the first light emission control transistor T41 and the second light emission control transistor T42 are P-type transistors.

A first terminal of the second light emission control transistor T42 is connected to the second terminal of the driving transistor DTFT, a second terminal of the second light emission control transistor T42 is connected to an anode of a light emitting element D1, and a gate of the second light emission control transistor T42 is configured to receive the light emission control signal EM. A cathode of the light emitting element D1 is connected to a second power supply line VSS.

The pixel circuit 20 further includes a storage capacitor Cst, a first terminal of the storage capacitor Cst is connected to the first power supply line VDD, and the first terminal of the storage capacitor Cst is configured to receive a first power supply voltage, and a second terminal of the storage capacitor Cst is connected to the gate of the driving transistor DTFT.

The above specific embodiments do not constitute a limitation on the protection scope of the present application. A person should understand that various modifications, combinations, sub-combinations and substitutions may be made according to design requirements and other factors. Any modification, equivalent substitution and improvement made within a spirit and a principle of the present application shall be included within the protection scope of the present application.

What is claimed is:

1. A shift register, wherein the shift register comprises:
a first control module comprising a first node, and being configured to transmit a first power supply signal or a second power supply signal to the first node according to a first clock signal, an inverted signal of the first clock signal and an input signal, wherein, a potential of the first power supply signal and a potential of the second power supply signal are different;
a second control module comprising a second node, the second control module being connected to the first node, and being configured to transmit the first power supply signal or a third power supply signal to the second node under control of at least the potential of the first node, to output an inverted potential of the first node at the second node;
a first output module comprising a first output terminal, the first output module being connected to the first node and the second node respectively, and being configured to transmit a first output signal having the potential of the first power supply signal to the first output terminal in response to the potential of the first node, or transmit the first output signal having the potential of the second power supply signal to the first output terminal in response to a potential of the second node; and
a second output module comprising a second output terminal, the second output module being connected to the second node and a third node respectively,
wherein a potential of the third node is an inverted potential of the potential of the second node, the second output module is configured to transmit a second output signal having the potential of the first power supply signal to the second output terminal in response to the potential of the second node, or transmit the second output signal having a potential of a second clock signal to the second output terminal in response to the potential of the third node.

2. The shift register according to claim 1, wherein the first control module comprises an input unit and a first control unit, and the input unit and the first control unit are connected at a fourth node;
the input unit is configured to receive the input signal, the first clock signal and the inverted signal of the first clock signal, and transmit the input signal to the fourth node according to the first clock signal and the inverted signal of the first clock signal;
the first control unit is configured to receive the first power supply signal and the second power supply signal respectively, and transmit the first power supply signal or the second power supply signal to the first node according to a potential of the fourth node;
the input unit comprises a first transistor and a second transistor, a gate of the first transistor is configured to receive the first clock signal, a first terminal of the first transistor is configured to receive the input signal, and a second terminal of the first transistor is connected to the fourth node;
a first gate of the second transistor is configured to receive the inverted signal of the first clock signal, a first terminal of the second transistor is configured to receive the input signal, and a second terminal of the second transistor is connected to the fourth node; and a channel type of the second transistor and a channel type of the first transistor are opposite.

3. The shift register according to claim 2, wherein the second transistor further comprises a second gate, the second gate is configured to receive the third power supply signal; the inverted signal of the first clock signal comprises a high potential signal and a low potential signal, and a voltage of the third power supply signal is lower than a voltage of the low potential signal in the inverted signal of the first clock signal.

4. The shift register according to claim 2, wherein the first control unit comprises a first inverter unit and a storage unit;
a control terminal of the first inverter unit is connected to the fourth node, a first terminal of the first inverter unit is configured to receive the first power supply signal, a second terminal of the first inverter unit is configured to receive the second power supply signal, and the first inverter unit is configured to invert the potential of the fourth node and output the inverted potential to the first node;
a first terminal of the storage unit is connected to the fourth node, a second terminal of the storage unit is connected to the second terminal of the first inverter unit, and is configured to store the potential of the fourth node;
the first inverter unit comprises a third transistor and a fourth transistor;
a first gate of the third transistor serves as the control terminal of the first inverter unit, a first terminal of the third transistor serves as the second terminal of the first inverter unit, and a second terminal of the third transistor is connected to the first node;
a gate of the fourth transistor is connected to the first gate of the third transistor, a first terminal of the fourth transistor serves as the first terminal of the first inverter unit, and a second terminal of the fourth transistor is connected to the first node;
the third transistor comprises a second gate, the second gate of the third transistor is configured to receive a fourth power supply signal; the input signal comprises a high potential signal and a low potential signal, and a voltage of the fourth power supply signal is lower than a voltage of the low potential signal in the input signal;
the storage unit comprises a first capacitor, a first terminal of the first capacitor serves as the first terminal of the storage unit, and a second terminal of the first capacitor serves as the second terminal of the storage unit.

5. The shift register according to claim 2, wherein the second control module is further connected to the second node, the third node and the fourth node respectively, and is configured to
transmit the first power supply signal to the second node in response to the potential of the first node, and transmit the third power supply signal to the third node according to the first power supply signal at the second node; and
configured to transmit the first power supply signal to the third node in response to the potential of the fourth node, and transmit the third power supply signal to the second node according to the first power supply signal at the third node; and
a voltage of the third power supply signal is lower than a voltage of the second power supply signal.

6. The shift register according to claim 2, wherein the second control module comprises a fifth transistor, a sixth transistor, a seventh transistor and an eighth transistor;
a gate of the fifth transistor is connected to the fourth node, a first terminal of the fifth transistor is configured to receive the first power supply signal, and a second terminal of the fifth transistor is connected to the third node;
a gate of the sixth transistor is connected to the first node, a first terminal of the sixth transistor is configured to receive the first power supply signal, and a second terminal of the sixth transistor is connected to the second node;
a first gate of the seventh transistor is connected to the second node, a first terminal of the seventh transistor is configured to receive the third power supply signal, and a second terminal of the seventh transistor is connected to the third node;
a first gate of the eighth transistor is connected to the third node, a first terminal of the eighth transistor is configured to receive the third power supply signal, and a second terminal of the eighth transistor is connected to the second node;
wherein, a channel type of the fifth transistor is opposite to a channel type of the seventh transistor, a channel type of the sixth transistor is opposite to a channel type of the eighth transistor, and the channel type of the fifth transistor is the same as the channel type of the sixth transistor;
the seventh transistor and the eighth transistor respectively comprise a second gate, the second gate of the seventh transistor and the second gate of the eighth transistor are respectively configured to receive a fifth power supply signal; and a voltage of the fifth power supply signal is lower than the voltage of the third power supply signal.

7. The shift register according to claim 1, wherein the first node is multiplexed as the third node, and the second control module comprises a second inverter unit;
a control terminal of the second inverter unit is connected to the first node, a first terminal of the second inverter unit is configured to receive the first power supply signal, a second terminal of the second inverter unit is configured to receive the second power supply signal, and the second inverter unit is configured to invert the potential of the first node and output the inverted potential to the second node;
the second inverter unit comprises a ninth transistor and a tenth transistor, a gate of the ninth transistor serves as the control terminal of the second inverter unit, a first terminal of the ninth transistor serves as the first terminal of the second inverter unit, and a second terminal of the ninth transistor is connected to the second node;
a gate of the tenth transistor is connected to the gate of the ninth transistor, a first terminal of the tenth transistor serves as the second terminal of the second inverter unit, and a second terminal of the tenth transistor is connected to the second node.

8. The shift register according to claim 1, wherein the first output module comprises: a first output unit and a second output unit;
the first output unit is connected to the first node, and is configured to transmit the first power supply signal to the first output terminal according to the potential of the first node;
the second output unit is connected to the second node, and is configured to transmit the second power supply signal to the first output terminal according to the potential of the second node;
the first output unit comprises an eleventh transistor, a gate of the eleventh transistor is connected to the first node, a first terminal of the eleventh transistor is configured to receive the first power supply signal, and a second terminal of the eleventh transistor is connected to the first output terminal;
the second output unit comprises a twelfth transistor, a gate of the twelfth transistor is connected to the second node, a first terminal of the twelfth transistor is connected to the second terminal of the eleventh transistor and is connected to the first output terminal, and a second terminal of the twelfth transistor is configured to receive the second power supply signal.

9. The shift register according to claim 1, wherein the second output module comprises a third output unit and a fourth output unit;
the third output unit is connected to the second node, and is configured to transmit the first power supply signal to the second output terminal according to the potential of the second node;
the fourth output unit is connected to the third node, and is configured to transmit the second clock signal to the second output terminal according to the potential of the third node;
the third output unit comprises a thirteenth transistor, a gate of the thirteenth transistor is connected to the second node, a first terminal of the thirteenth transistor is configured to receive the first power supply signal, and a second terminal of the thirteenth transistor is connected to the second output terminal;
the fourth output unit comprises a fourteenth transistor and a second capacitor, a gate of the fourteenth transistor is connected to the third node and a first terminal of the second capacitor, a first terminal of the fourteenth transistor is connected to a second terminal of the second capacitor and is connected to the second output terminal, and a second terminal of the fourteenth transistor is configured to receive the second clock signal.

10. The shift register according to claim 9, wherein the shift register further comprises a potential isolation module, a control terminal of the potential isolation module is configured to receive the third power supply signal, a first terminal of the potential isolation module is connected to the third node, a second terminal of the potential isolation module is connected to a control terminal of the fourth output unit; and
a voltage of the third power supply signal is lower than a voltage of a low potential signal in the second clock signal;
the potential isolation module comprises a fifteenth transistor; a gate of the fifteenth transistor serves as the control terminal of the potential isolation module, a first terminal of the fifteenth transistor serves as the first terminal of the potential isolation module, and a second terminal of the fifteenth transistor serves as the second terminal of the potential isolation module.

11. The shift register according to claim 2, wherein the first clock signal and the second clock signal have a same period, and an effective potential signal of the first clock signal and an effective potential signal of the second clock signal at least partially overlap;
the effective potential signal of the first clock signal is a signal that turns on the input unit, and the effective potential signal of the second clock signal is a signal that turns on a transistor connected to the second output terminal;
a duration of the effective potential signal of the second clock signal is less than a duration of the effective potential signal of the first clock signal.

12. The shift register according to claim 1, wherein a potential corresponding to the second power supply signal is an effective potential of the first output signal, a first potential signal in the second clock signal is an effective potential of the second output signal, the effective potential of the first output signal is a potential signal that turns on a transistor connected to the first output terminal, and the effective potential of the second output signal is a potential signal that turns on a transistor connected to the second output terminal;
the second clock signal comprises the first potential signal and a second potential signal, one of the first potential signal and the second potential signal is a high potential signal, and another of the first potential signal and the second potential signal is a low potential signal.

13. The shift register according to claim 12, wherein within one frame, a duration of the effective potential of the first output signal is greater than a duration of the effective potential of the second output signal.

14. A gate driving circuit, comprising the shift register according to claim 1,
wherein the gate driving circuit comprises m number of shift register groups, m is an integer greater than or equal to 1, a shift register group comprises k number of the shift registers, the k number of the shift registers are connected in a cascade connection through the first output terminal, a first stage shift register in the shift register group is configured to receive the input signal; k is an integer greater than or equal to 2;
the gate driving circuit further comprises a first clock signal line, a second clock signal line, a first inverted clock signal line, a second inverted clock signal line and m number of groups of third clock signal lines, each group of the third clock signal lines comprises two third clock signal lines;
the first clock signal line is configured to provide a first clock signal to an i-th stage of the shift register, the second clock signal line is configured to provide the first clock signal to a j-th stage of the shift register, wherein i is an odd number greater than or equal to 1 and less than or equal to k, and j is an even number greater than 1 and less than or equal to k; the first inverted clock signal line is configured to provide an inverted signal of the first clock signal to the i-th stage of the shift register, the second inverted clock signal line is configured to provide the inverted signal of the first clock signal to the j-th stage of the shift register;
one of the third clock signal lines in a p-th group of the third clock signal lines is connected to an odd stage of the shift register in a p-th shift register group, another of the third clock signal lines in the p-th group of the third clock signal lines is connected to an even stage of the shift register in the p-th shift register group, and p is greater than or equal to 1 and less than or equal to m.

15. The gate driving circuit according to claim 14, wherein a signal transmitted by the second clock signal line and a signal transmitted by the first clock signal line have an equal period, and the signal transmitted by the second clock signal line has a phase delay relative to the signal transmitted by the first clock signal line;
a signal transmitted by the second inverted clock signal line and another signal transmitted by the first inverted clock signal line have an equal period, and the signal transmitted by the second inverted clock signal line has a phase delay relative to a signal transmitted by the first inverted clock signal line;
in each group of the third clock signal lines, a phase of a signal transmitted by the third clock signal line connected to the even stage of the shift register has a phase delay relative to another phase of another signal transmitted by the third clock signal line connected to the odd stage of the shift register;
in two groups of the third clock signal lines corresponding to two adjacent groups of the shift register groups, a signal transmitted by the third clock signal line connected to the odd stage of the shift register in a latter group of the two groups of the third clock signal lines has a phase delay relative to another signal transmitted by the third clock signal line connected to the even stage of the shift register in a former group of the two groups of the third clock signal lines.

16. The gate driving circuit according to claim 15, wherein a first delay time is equal to a second delay time;
wherein the first delay time is a phase delay time of the signal transmitted by the second clock signal line relative to the signal transmitted by the first clock signal line;
the second delay time is a phase delay time of the signal transmitted by the third clock signal line connected to the odd stage of the shift register in the latter group of the two groups of the third clock signal lines relative to the signal transmitted by the third clock signal line connected to the even stage of the shift register in the former group of the two groups of the third clock signal lines, in the two groups of the third clock signal lines corresponding to the two adjacent groups of the shift register groups,
or, the second delay time is a phase delay time of the phase of the signal transmitted by the third clock signal line connected to the even stage of the shift register relative to the phase of the signal transmitted by the third clock signal line connected to the odd stage of the shift register in each group of the third clock signal lines.

17. A driving method for a shift register, applied to the shift register according to claim 1, wherein the driving method comprises:
transmitting, by a first control module, a first power supply signal or a second power supply signal to a first node according to a first clock signal, an inverted signal of the first clock signal and an input signal; wherein a potential of the first power supply signal and a potential of the second power supply signal are different;
transmitting, by a second control module, the first power supply signal or a third power supply signal to a second node under control of at least a potential of the first node, to output an inverted potential of the first node at the second node;
transmitting, by a first output module, a first output signal having the potential of the first power supply signal to a first output terminal in response to the potential of the first node, or transmitting the first output signal having a potential of the second power supply signal to the first output terminal in response to a potential of the second node;
transmitting, by a second output module, a second output signal having the potential of the first power supply signal to a second output terminal in response to the potential of the second node, or transmitting the second output signal having a potential of a second clock signal to the second output terminal in response to a potential of a third node; wherein the potential of the third node is inverted to the potential of the second node.

18. The driving method for a shift register according to claim 17, wherein the first control module comprises an input unit and a first control unit;
the transmitting, by the first control module, the first power supply signal or the second power supply signal to the first node according to the first clock signal, the inverted signal of the first clock signal and the input signal comprises:
transmitting, by the input unit, the input signal to a fourth node according to the first clock signal and the inverted signal of the first clock signal;
transmitting, by the first control unit, the first power supply signal or the second power supply signal to the first node according to a potential of the fourth node;
the first control unit comprises a first inverter unit and a storage unit;
the transmitting, by the first control unit, the first power supply signal or the second power supply signal to the first node according to the potential of the fourth node comprises:
inverting, by the first inverter unit, the potential of the fourth node and outputting the inverted potential to the first node;
storing, by the storage unit, the potential of the fourth node.

19. The driving method for a shift register according to claim 18, wherein the transmitting, by the second control module, the first power supply signal or the third power supply signal to the second node under control of at least the potential of the first node, to output the inverted potential of the first node at the second node comprises:
transmitting, by the second control module, the first power supply signal to the second node in response to the potential of the first node, and transmitting the third power supply signal to the third node according to the first power supply signal at the second node;
transmitting the first power supply signal to the third node in response to the potential of the fourth node, and transmitting the third power supply signal to the second node according to the first power supply signal at the third node; wherein a voltage of the third power supply signal is lower than a voltage of the second power supply signal.

20. A display panel, wherein the display panel comprises the gate driving circuit according to claim 13, and further comprises a pixel circuit, the pixel circuit comprises a data writing transistor, a compensation transistor, an initialization transistor and a light emission control transistor;
a first output terminal of the gate driving circuit is connected to a gate of the light emission control transistor, and is configured to provide a light emission control signal to the light emission control transistor;
a second output terminal of the gate driving circuit is connected to a gate of the data writing transistor, a gate of the compensation transistor or a gate of the initialization transistor, and is configured to provide a scanning signal to the data writing transistor, the compensation transistor or the initialization transistor.
